(19) United States
(12) Patent Application Publication
(10) Pub. No.: US 2006/0157347 A1
(43) Pub. Date: Jul. 20, 2006

(54) Reduced maintenance sputtering chambers

(76) Inventor: Klaus Hartig, Avoca, WI (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 11/330,787

(22) Filed: Jan. 12, 2006

Related U.S. Application Data
(60) Provisional application No. 60/643,955, filed on Jan. 13, 2005.

(51) Int. Cl. C23C 14/00

(52) U.S. Cl. 204/298.16

(57) ABSTRACT

Improved sputtering chambers for sputtering thin coatings onto substrates. One sputtering chamber includes spall shields which are disposed inwardly and upwardly toward the chamber interior and toward the sputtering targets, and which can aid in the retention of overcoated sputtering material which may otherwise fall onto substrates to be coated. Another sputtering chamber includes targets having magnets which are turned inwardly relative to vertical and toward each other. The inward rotation of the magnets can serve to deposit more material toward the open bottom center of the chamber, and less toward the side walls of the chamber. Yet another sputtering chamber includes a third target disposed between and upward of the lower two targets so as to shield a portion of the sputtering chamber interior from material sputtered from the first and second targets. Some chambers have the three targets forming a triangle, for example, an isosceles or equilateral triangle. In one chamber having such a triangular configuration of sputtering targets, the first and second targets form the base of an isosceles triangle and have their magnets oriented inwardly relative to vertical and towards each other. The sputtering chambers provided can either reduce the amount of overcoat sputtering material deposited onto the interior of the chamber and/or aid in retention of overcoat sputtering material which would otherwise fall onto substrates to be coated.

### FIELD OF THE INVENTION

The present invention relates generally to methods and devices for magnetron sputtering of material onto substrates. More particularly, the present invention relates to improved sputtering chamber designs.

### BACKGROUND OF THE INVENTION

Sputter deposition is a process for applying thin films onto substrates. Generally, the sputtering process occurs within a sputtering chamber within which a controlled environment can be established. A target or targets including a material to be deposited can be positioned within the sputtering chamber, and a power supply connected to the target to apply a cathodic charge to at least portions of the target. A relatively positively charged anode can be positioned within the sputtering chamber proximate the target. The chamber is evacuated and a plasma gas established within the chamber. Ions of the plasma gas are accelerated by electrical charges into the targets, causing particles of the targets to be physically ejected, sometimes chemically combining with ions of the plasma gas, and deposited on a substrate located within the sputtering chamber. It is also common to include a magnet behind the targets to help shape the plasma and focus the plasma in an area adjacent the surface of the targets.

Rotatable, cylindrical, magnetically enhanced targets are commonly used, in which the magnets are disposed behind the surfaces of the targets, generally facing toward the substrate to be coated, thus directing a larger portion of the sputtered material toward the substrate. Although the sputtered material is emitted generally orthogonally away from the targets into the area behind the magnets, material is sputtered from magnetically enhanced portions of the targets in a wide angle, and to some extent the sputtered material is redirected in all directions as a result of the gas scattering effect that follows. Therefore, not all of the sputtered material ends up being deposited upon the substrate. The remainder of the sputtered material, which can be on the order of about 5-10% of the total sputtered material, coats the interior surfaces, which can include the ceiling, walls, and any other exposed surfaces within the chamber, such as end blocks, anodes, and gas distribution pipes. This is sometimes referred to as “overcoating.” Overcoating is a significant problem for a number of reasons. As noted above, it accounts for a significant amount of lost coating. It also necessitates periodic removal of overcoated material from the interior surfaces of the chamber. Removal is difficult and time-consuming. Removal can cause process downtime periods lasting several hours or more which is terribly economically inefficient.

In addition, the overcoated material deposited on the interior surfaces of a sputtering chamber tends to exhibit spalling during the heating and cooling cycles that are typically experienced by sputtering chambers. For example, the overcoated surfaces of a vacuumized sputtering chamber tend to heat up during sputtering. When sputtering is stopped and the chamber is shut down, for example, to change targets, the overcoated chamber surfaces cool down. Flakes of sputtered material may then begin to spall from the overcoated surfaces of the chamber. This spalling is believed to occur because the coefficient of thermal expansion of the deposited material is often very different from the coefficient of thermal expansion of the interior surfaces of the sputtering chamber. As the sputtering chamber undergoes temperature change, condensate on the interior surfaces of the chamber expands and contracts at a first thermal expansion rate, which rate depends on the thermal expansion coefficient of the sputtered material. At the same time, the chamber surfaces expand and contract at a second thermal expansion rate dependent upon the thermal expansion coefficient of the material from which the chamber surfaces are formed. When these rates are different, stress can build up within the overcoated material until particles of this material flake or pop from the interior surfaces of the chamber. These flakes of overcoat can fall upon the substrate being coated, causing damage through inclusions, pinholes, and other defects to the coating deposited on the substrate. Thus, once a chamber is shut down and flakes of sputtered material begin to fall, sputtering is typically not resumed until the shower of spalling flakes subsides. Unfortunately, flakes of sputtering material may spall from the interior surfaces of a sputtering chamber for significant periods of time, which can be on the order of one to two hours in some cases. As industrial sputtering lines are extraordinarily expensive, the productivity lost by this added down time is terribly inefficient and costly.

What would be desirable is a sputtering chamber adapted to reduce the amount of sputtered material dropping from the interior surfaces of the sputtering chamber. What would also be desirable is a sputtering chamber which deposits less sputtered material onto the sputtering chamber side walls.

### SUMMARY OF THE INVENTION

The present invention provides a first improved sputtering chamber having a first and second sputtering target, each target having at least one magnet therein. The magnets are preferably arcuately disposed about the central longitudinal axis of the targets. The magnets are preferably oriented inward relative to vertical and toward each other so as to cause less overcoat sputtering onto the side walls of the chamber, with more sputtering directed toward the central, bottom portion of the chamber. In one chamber, the degree of rotation or orientation of the magnets from vertical may be defined by angles alpha 1 and alpha 2, for the first and second targets respectively. The angles alpha 1 and alpha 2 can quantify the degree of rotation by measuring the angle between a vertical plane extending through the target central axis and a plane extending through the target central axis and bisecting the target magnet.

In a second chamber according to the present invention, improved spall shields are provided. The spall shields can be oriented upwardly and inwardly toward the chamber interior and toward the targets within the chamber interior. The upwardly and inwardly oriented spall shields can serve to retain overcoat sputtering material which might otherwise flake off and drop onto substrates to be coated. In one chamber according to this aspect of the invention, the spall shields curve upwardly and inwardly, and have an arcuate shape terminating in a tip. In another embodiment, the spall shields form a continuous arcuate curve with the side walls of the chamber. In yet another embodiment, the spall shields are substantially straight, having a straight portion extending upwardly and inwardly toward the chamber interior.

In a third aspect of the intention, a third target can be disposed upwardly and between the lower first and second targets. The third target can serve to shield an upper portion of the sputtering chamber interior from sputtering material deposited by the first and second targets below. The third, upper target can be the same size or a different size relative to the first and second targets below. The third target is preferably closely spaced to the first and second target to reduce the amount of unwanted sputtering and overcoating on the chamber interior. In one embodiment, the first and second, lower targets have arcuate magnets oriented inwardly relative to vertical, while the third, upper magnet is oriented vertically downward. The second and third target can shield a portion of the chamber interior from the first target, and the first and third target can shield a portion of the chamber from the second target. In one embodiment, the first, second, and third targets form an isosceles triangle. In another embodiment, the first, second and third targets form an equilateral triangle. In one embodiment, at least one of the targets is cantilevered off of a front or rear wall. In another embodiment, the lower, first and second targets are cantilevered off of a rear wall, while the third, upper target is cantilevered off of a front wall.

### DESCRIPTION OF THE DRAWINGS

FIG. 1 is a highly diagrammatic, end view of a prior art sputtering chamber having two cylindrical targets disposed over a substrate to be coated, and horizontal ledges or spall shields having overcoat material deposited thereon;

FIG. 2 is a highly diagrammatic, cross sectional end view of a sputtering chamber including arcuate target magnets turned inwardly toward each other relative to vertical;

FIG. 3A is a highly diagrammatic, cross sectional end view of a sputtering chamber having spall shields or ledges oriented upwardly and inwardly toward the chamber interior;

FIG. 3B is a detail view of another embodiment similar to that of FIG. 3A, having an inwardly and upwardly oriented arcuate spall shield;

FIG. 3C is a detailed view of a sputtering chamber spall shield oriented upwardly and inwardly toward the chamber interior and forming a continuous arc with the chamber side wall;

FIG. 4A is a highly diagrammatic transverse cross sectional end view of a sputtering chamber having first and second targets, and further having a third target disposed inwardly and upwardly of the first and second targets so as to shield a portion of the sputtering chamber side walls from overcoating;

FIG. 4B is a highly diagrammatic, detailed view of the three targets of 4A, illustrating one example of relative dimensions and spacings of the three targets; and

FIG. 4C is a highly diagrammatic, side view of the sputtering chamber of FIG. 4A, illustrating the targets being cantilevered off the front and rear walls.

### DETAILED DESCRIPTION OF THE PREFERRED EMBODIMENTS

The following detailed description should be read with reference to the drawings, in which like elements in different drawings are numbered identically. The drawings, which are not necessarily to scale, depict selected embodiments and are not intended to limit the scope of the invention. Several forms of invention have been shown and described, and other forms will now be apparent to those skilled in art. It will be understood that embodiments shown in drawings and described above are merely for illustrative purposes, and are not intended to limit scope of the invention as defined in the claims which follow.

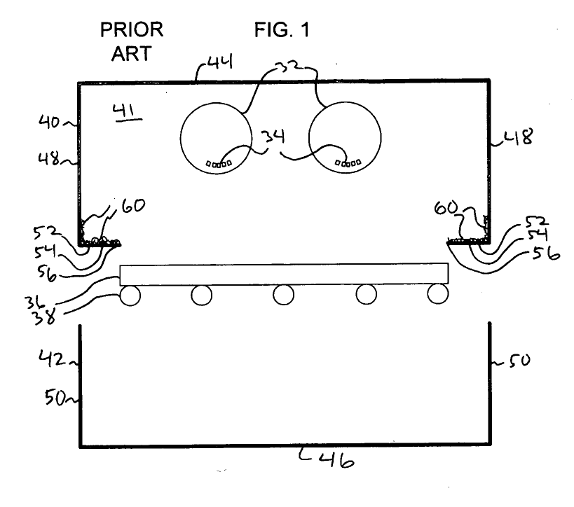

FIG. 1 illustrates a prior art sputtering chamber 30 having a top portion 40 and a bottom portion 42. Top portion 40 includes generally an interior 41, a ceiling 44, side walls 48, and lower ledges or spall shields 52. Spall shield 52 may be seen to have an inward-most extent or tip 56 and a ledge portion 54. Spall shields 52 may be seen to be substantially horizontal to ceiling 44 and are generally horizontal to the ground. Overcoat sputtering material 60 may be seen built up on spall shields 52, and in the corners and side wall portions adjacent to spall shields 52.

Sputtering chamber 30 may be seen to have cylindrical targets 32, each having arcuate magnets 34 oriented downward toward a substrate 36 which is disposed on rollers 38. Sputtering chamber bottom portion 42 may be seen to have a floor 46 and bottom side walls 50. In use, sputtering chamber 30 is typically substantially evacuated and contains an ionized gas forming a plasma. The plasma ions strike the cylindrical sputtering targets 32, thereby physically dislodging particles of target material. A cloud of ejected particles, or a plasma vapor, may be created within the sputtering chamber interior 41. During sputtering, a thin film of particles of target material may be formed on substrate 36. As may be seen from inspection of FIG. 1, a significant amount of overcoat sputtering material is formed onto the side walls of the sputtering chamber top portion 40, and on spall shields 52. As described in the background section, this material can fall onto the substrate 36.

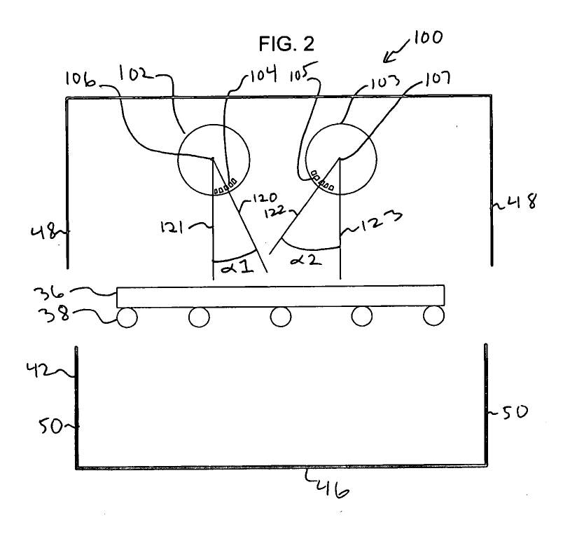

Referring now to FIG. 2, the top portion of an improved sputtering chamber 100 is illustrated. Sputtering chamber 100 has a first target 102 having a longitudinal central axis 106 and a second target 103 having a longitudinal central axis 107. First target may be seen to have a first arcuate magnet 104 disposed angularly or arcuately about central axis 106. In a preferred embodiment, magnet 104 is formed with several discrete elongate bar shaped magnets held together in an arcuate shape by a curved, elongate carrier. The magnet subcomponent bars may appear rectangular when viewed from the side, and square when viewed from the end. Magnet 104 may be seen to be bisected by a line or a plane 120 extending through the first target central axis 106. A line or plane 121 may be seen extending vertically downward through the first target central axis 106. Magnet 104 may be seen to be turned inwardly toward the second target 103 relative to vertical. In particular, the inward turning of magnet 104 may be seen to form a first angle alpha 1 between plane 120 and plane 121. Angle alpha 1 thus describes the angle from vertical formed by the inward turning of first target magnet 104.

Second target 103 can be seen to have magnet 105 which is similarly bisected by a line or a plane 122 bisecting the magnet and extending through second target's cylindrical axis 107. A line or plane 123 may be seen to extend vertically through a second target central axis 107. A second angle alpha 2 may be seen to describe the degree of inward rotation of angular magnet 105 inward relative to vertical and toward first target 102.

Thus, it can be appreciated that both magnets 104, 105 are toed inwardly in the embodiment of FIG. 2. In various embodiments of the invention, angles alpha 1 and alpha 2 may be either substantially identical or different. In a preferred embodiment, angles alpha 1 and alpha 2 are substantially equal to each other. In one embodiment, angles alpha 1 and alpha 2 are between about 10° and 40° inward of vertical. In another embodiment, angles alpha 1 and alpha 2 are between about 20° and 35° inward of vertical. In yet another embodiment, angles alpha 1 and alpha 2 are about 30° inward of vertical. In most cases, it will be preferable to toe both magnets 104, 105 inwardly by up to about 35 degrees. However, it may be advantageous to toe only one of the targets 102, 103 inwardly, for example, by up to about 35 degrees.

As may be seen from inspection of FIG. 2, the inward orientation of magnets 104 and 105 will cause more sputtering material to be deposited toward the center of the sputtering chamber lower opening and less toward side walls 48. The reduced overcoating of side walls 48 is believed to reduce the amount of overcoat droppage which can occur.

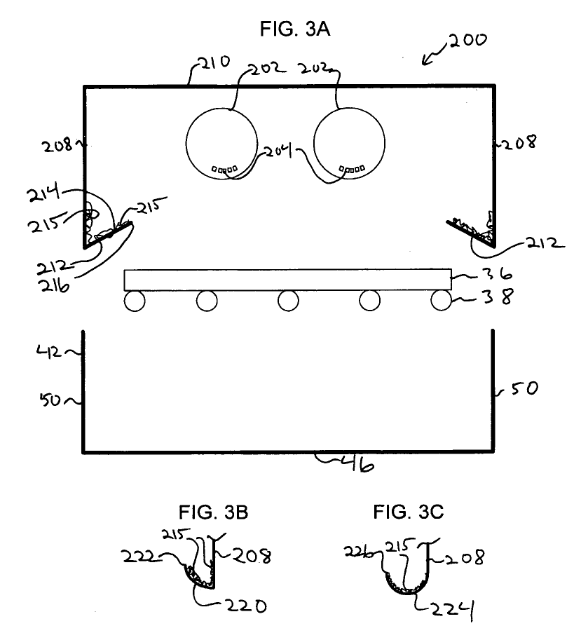

Referring now to FIGS. 3A through 3C, the top portion of another sputtering chamber 200 is illustrated. Sputtering chamber 200 includes a ceiling 210, side walls 208, and upwardly and inwardly disposed spall shields 212. While two spall shields are depicted in FIG. 3A, it is to be understood that the chamber 200 may alternatively be provided with a single spall shield of the described nature. Spall shields 212 may be seen to have an inward tip 216 and a ledge portion 214. Overcoating material 215 may be seen deposited on the spall shields. The sputtering chamber illustrated in FIG. 3A includes two cylindrical targets 202, each having magnets 204. However, it is to be understood that any number and type of targets can be provided in a sputtering chamber having the disclosed spall shields. The spall shields could, for example, number one or two, and be either cylindrical or planar.

In the embodiment of FIG. 3A, the ledge portion 214 of each spall shield 212 forms an acute inside angle with the chamber side wall 208. This angle is preferably between about 45 degrees and about 85 degrees, more preferably between about 80 degrees and about 50 degrees, and perhaps optimally about 65 degrees. In other words, the tip 216 of each shield 212 is preferably at a higher vertical location within the chamber than the point at which the ledge 214 diverges from the chamber sidewall 208. In other terms the ledge 214 of each shield 212 lies in a plane that is inclined from the chamber sidewall 208 to the inward tip 216 of the shield. The ledge 214 of each shield preferably forms an acute angle preferably between about 5 degrees and about 45 degrees, more preferably between about 10 degrees and about 40 degrees, and perhaps optimally about 25 degrees with respect to the path of substrate travel, where the substrate travel can be horizontal.

FIG. 3B illustrates a detailed view of one embodiment similar to sputtering chamber 200 of FIG. 3A. In the embodiment of FIG. 3B, side wall 208 forms a corner with an arcuate upwardly curved spall shield 220 terminating in an upward and inward tip 222. Overcoat material 215 may be seen deposited on the interior of spall shield 220. FIG. 3C also illustrates an embodiment similar to that of FIG. 3A, having side wall 208 forming a continuous curve with a curved spall shield 224 terminating in an upward and inward tip 226. Material 215 may be seen held within arcuate spall shield 224.

It can be appreciated that the spall shields in the embodiments of FIGS. 3A-3C extend inwardly from the chamber sidewall and generally toward the targets. Thus, the surface of each spall shield forms a relatively small or “flat” angle with respect to the targets, that is, forms a small angle with respect to a line or plane extending from the spall shield to the central axis of the adjacent target. As a consequence, much of the sputtered material that lands upon each spall shield will have a relatively small angle of incidence with respect to the ledge 214 of the shield. Thus, sputtered material is expected to accumulate on the present spall shield more slowly than in prior art spall shields like that depicted in FIG. 1. Moreover, it is believed that the present spall shields will retain more overcoating material 215, even if such material begins to spall from the shields. For example, spalling flakes of overcoating material 215 would be expected to pop orthogonally from the shields. Thus, with the present shields, these flakes may be more likely to pop upwardly and somewhat toward the chamber sidewall, preferably being caught again by the ledge 214 of each shield, rather than falling upon the substrate.

In one preferred embodiment, there is provided a sputtering chamber having two cylindrical targets with inwardly-turned magnets, as previously described with reference to FIG. 2A, and at least one upwardly and inwardly extending spall shield, as previously described with reference to FIGS. 3A-3C. A sputtering chamber with this combination of features would provide particular benefit in the way of spalling reduction.

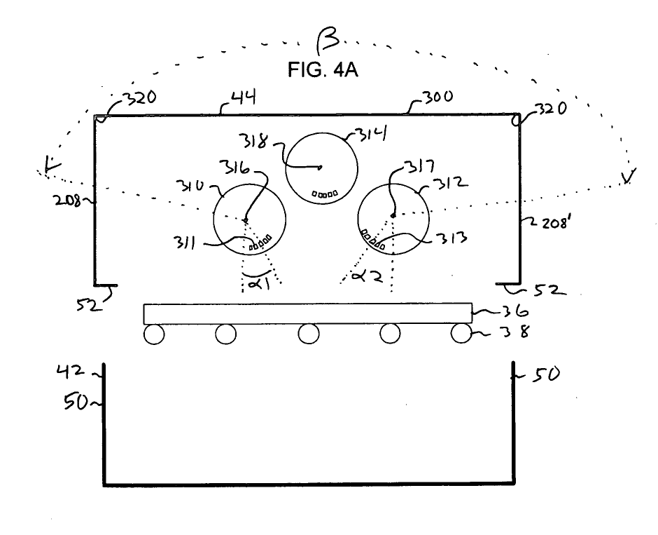

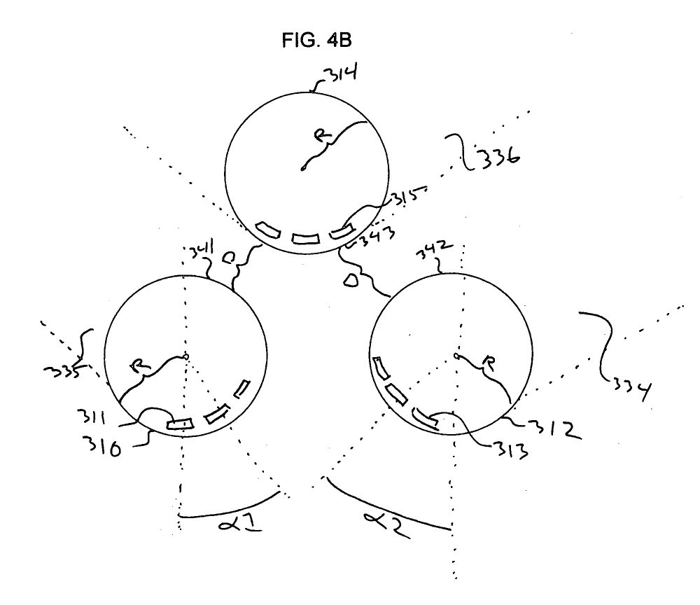

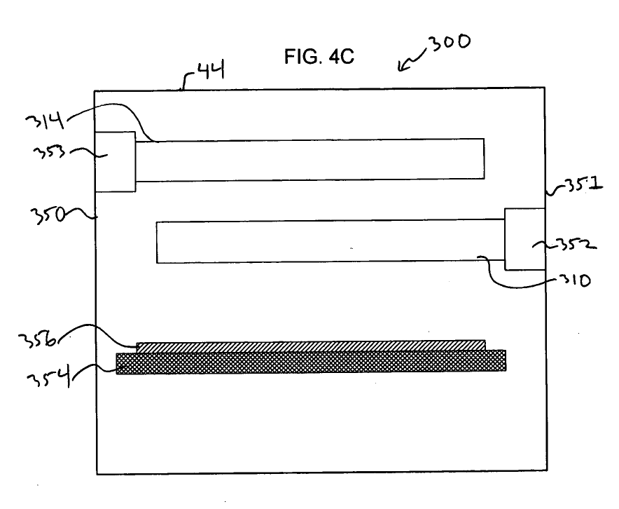

FIGS. 4A through 4C illustrate yet another embodiment of the invention. A sputtering chamber 300 may be seen, including a top portion having a ceiling 44 and side walls 208. Optional spall shields 52 may be seen disposed at the bottom, side corners of the sputtering chamber upper portion. Sputtering chamber 300 may be seen to have a first, lower target 310 having an arcuate magnet 311, a second, lower target 312 having a second arcuate magnet 313, and a third, upper target 314 having an arcuate magnet 315. The first, second and third targets are cylindrical targets and may be seen to be enclosed within a sputtering enclosure having a ceiling 44 and side walls 208, as well as optional spall shields 52. The first, second and third targets may be seen to have longitudinal central axes 316, 317, and 318, respectively.

As may be seen from inspection of FIG. 4A, the third target 314 can serve to shield the interior of sputtering chamber 300, in part, from overcoating of sputtering material. In particular, the chamber ceiling 44 may be shielded. In one embodiment, the first and second targets 310 and 312 have magnets 311 and 312 oriented inwardly rather than vertically by angles alpha 1 and alpha 2, as previously described with respect to FIG. 2. This serves to substantially confine the plasma in a central region generally intermediate of the three targets. This further reduces the amount of overcoat material deposited on side walls 208. In the embodiment illustrated, the portion of sputtering chamber 300 shielded in part by the presence of third target 314 is illustrated by angle beta. Thus, it can be appreciated that the present cathode configuration provides a shielding function whereby the ceiling 44, upper corners 320, and upper portions of the chamber sidewalls are shielded from the sputtered target material. In effect a large portion of the high exposure chamber surfaces are self cleaning, as material landing back on the targets can be removed by the normal sputtering process.

Referring now to FIG. 4B, the three targets of FIG. 4A are illustrated in detail. First and second targets 310 and 312 may be seen to have a radius as indicated at “R.” In the embodiment illustrated, third target 314 also has a radius “R,” which is not necessarily identical to the radius of first and second targets, depending on the embodiments. The first target 310 magnets 311 may be seen angled inwardly by angle alpha 1 relative to vertical, and second target 312 may be seen to have magnets 313 angled inwardly by an angle alpha 2 relative to vertical. As noted above, this serves to substantially confine the plasma in a central region of the chamber and is believed to result in the deposit of less material onto the sputtering chambers side walls.

In the embodiment illustrated, magnets 315 in third target 314 are oriented directly vertically downward. In one embodiment, a line or plane extending through the axis of the first target 310 and through the axis of the second target 312 forms the base of an isosceles triangle, with third target 314 forming the apex of the isosceles triangle. In another embodiment, first target 310 and second target 312 form the base of an equilateral triangle, with third target 314 forming the apex of that equilateral triangle. In yet another embodiment, third target 314 is disposed substantially close to first target 310 and second target 312. That is, the two outermost side extents (the two opposed sides, respectively nearest the two opposed chamber sidewalls 208) of the third target may be nearer, or equidistant, to the adjacent chamber sidewall than the innermost side extent of the adjacent first or second target. Alternatively or additionally, the bottom most side extent (the bottom side, nearest the path of substrate travel) of the third target may be nearer, or equidistant, to the path of substrate travel than the uppermost side extents of the first and second targets.

First target 310 has an outer surface 341, second target 312 has an outer surface 342, and third target 314 has an outer surface 343. First target 310 may be seen disposed at a distance “D” from third target 314, measured as the shortest distance between outer surfaces 341 and 343. Similarly, second target 312 may be seen disposed at distance “D” from third target 314, as measured by the distance between outer surfaces 342 and 343.

Various shielded areas may be seen by referring to FIG. 4B. Second target 312 may be seen to form a shielded area 334 from first target 310 and third target 314. Similarly, first target 310 may be seen to shield area 335 from second target 312 and third target 314. Finally, third target 314 may be seen to form a shielded area 336 from first target 310 and second target 312. Thus, it can be appreciated how the interior walls of the sputtering chamber may be substantially shielded from sputtering overcoat material forming on that interior. Moreover, it can be appreciated that the three targets in this embodiment are advantageously cylindrical targets, as this facilitates spacing the targets closely together, as described.

In one preferred embodiment, a sputtering chamber like that shown in FIG. 4A is also provided with spall shields that extend inwardly and upwardly generally toward the targets. Spall shields of this nature have been described, and are particularly advantageous when provided in combination with the described three-cylindrical-target arrangement. Thus, a sputtering chamber is provided with both features in one preferred embodiment.

FIG. 4C illustrates a transverse, side view of one particular embodiment of chamber 300 of FIG. 4A. In FIG. 4C, the chamber 300 may be seen to have ceiling 44 as well as a front side wall 350 and a rear wall 351. A first cantilever support or “end block” 352 may be seen supporting first target 310. The second target (not shown in FIG. 4C) may also be cantilevered in this manner, and from the same chamber sidewall as the first target. A third cantilever support 353 may be seen supporting third target 314. Cantilevered cylindrical rotating magnetrons of this nature are commercially available from Sinvaco, N.V., which is located in Zulte, Belgium. If so desired, each target can alternatively be supported by conventional dual end blocks with one end block supporting each end of each target. In the illustrated embodiment, the first and second targets are cantilevered off the front wall 350 of the chamber, while the third target is cantilevered off the rear wall 351 of the chamber, although this is by no means a requirement. The orientation of targets 310, 312, and 314 relative to substrate 356 disposed on roller 354 may be seen by viewing FIG. 4C.

The embodiments of the invention previously illustrated form improved sputtering chambers with respect to either formation of overcoating sputtering material on the chamber interior in various portions and/or improved retention of overcoat sputtering material which is deposited on the side walls.

1. A sputtering chamber for applying thin films onto substrates, the sputtering chamber comprising:
an enclosure including a ceiling portion and sidewall portions;
a first substantially cylindrical target and a second substantially cylindrical target, the targets each having a central longitude axis defining a target center, and an arcuate magnet disposed in an arc relative to the target center, the arc having a center point bisected by a plane extending through the target center, the first target magnet being turned inward of vertical and somewhat toward the second target, the second target being turned inward of vertical and somewhat toward the first target, such that a sputtered coating is directed preferentially between the first and second targets relative to the area outside of the first and second targets toward the side walls.

2. The sputtering chamber as in claim 1, wherein the first target magnet is turned inward by a first angle and the second target magnetic is turned inward by a second angle, wherein the first and second angles are approximately equal to each other.

3. A sputtering chamber as in claim 2, wherein the first and second angles are between about 10° and 40° inward of vertical.

4. A sputtering chamber as in claim 3, wherein the first and second angles are between about 15° and 35° inward of vertical.

5. A sputtering chamber as in claim 4, wherein the first and second angles are about 30° inward of vertical.

6. A sputtering chamber as in claim 2, wherein the first and second angles are about 35° inward of vertical.

7. A sputtering chamber for applying films onto substrates, the sputtering chamber comprising:
an enclosure including a top portion, the top portion having a ceiling portion and side wall portions, the side walls having bottom ledge portions which are disposed inwardly and upwardly into the top portion interior, wherein the enclosure top portion has an interior including at least one target.

8. A sputtering chamber as in claim 7, wherein the enclosure top portion bottom ledges are substantially straight and angled inwardly and upwardly from horizontal and toward the enclosure top portion ceiling.

9. A sputtering chamber as in claim 8, wherein the bottom ledges are angled upwardly and inwardly from horizontal by an angle of between about 15° and 35°.

10. A sputtering chamber as in claim 7, wherein the bottom ledges are curved inwardly and upwardly toward the enclosure ceiling.

11. A sputtering chamber as in claim 7, wherein the chamber enclosure top portion side walls and bottom ledges form a substantially continuous curve which extend inwardly and upwardly toward the top portion interior.

12. A sputtering chamber for applying films onto substrates, the sputtering chamber comprising:
a sputtering enclosure top portion including a ceiling, two side walls extending downwardly from the ceiling, and an interior; and
a first substantially cylindrical target and a second substantially cylindrical target each disposed within the enclosure top portion interior, the first and second cylindrical targets each having a magnet arcuately disposed about the cylindrical target central axis, further comprising a third substantially cylindrical target disposed upwardly and inwardly between the first and second targets.

13. A sputtering chamber as in claim 12, wherein the cylindrical target central axes are substantially parallel to each other.

14. A sputtering claim chamber as in claim 12, wherein the first and second target magnets are angularly oriented inwardly from vertical.

15. A sputtering chamber as in claim 14, wherein the first target magnet is turned inwardly from vertical at a first angle and the second target magnet is turned inwardly from vertical by a second angle, wherein the first and second angles are between about 10° and 45° inward of vertical.

16. A sputtering chamber as in claim 14, wherein the first and second magnet angles are between 20° and about 35° inward of vertical.

17. A sputtering chamber as in claim 12, wherein the first and second targets form the base of an isosceles triangle, and the third target forms the apex of the isosceles triangle.

18. A sputtering chamber as in claim 12, wherein the first and second targets form the base of an equilateral triangle and the third target forms the apex of the equilateral triangle.

19. A sputtering chamber as in claim 12, wherein the sputtering chamber has a front side wall and a rear side wall, wherein two of the targets are cantilevered off the front wall and one target is cantilevered off the rear wall.

20. A sputtering chamber as in claim 12, wherein the sputtering chamber has a front wall and a rear wall, wherein the first and second targets are cantilevered off of the front or rear wall and the third target is cantilevered off the opposite front or rear wall.

21. A sputtering chamber as in claim 12, wherein the third target is spaced substantially close to the first and second targets so as to shield the enclosure top portion corners from sputtering material, where the corners are formed where the top enclosure ceiling and top enclosure side walls meet.
